(19) United States
(12) Patent Application Publication
(10) Pub. No.: US 2013/0077268 A1
(43) Pub. Date: Mar. 28, 2013

(54) CIRCUIT BOARD WITH AIR HOLE

(71) Applicants: David L. Brunker, Naperville, IL (US); David E. Dunham, Aurora, IL (US); Kent E. Regnier, Lombard, IL (US); Michael J. Neumann, Woodridge, IL (US)

(72) Inventors: David L. Brunker, Naperville, IL (US); David E. Dunham, Aurora, IL (US); Kent E. Regnier, Lombard, IL (US); Michael J. Neumann, Woodridge, IL (US)

(73) Assignee: MOLEX INCORPORATED, Lisle, IL (US)

(21) Appl. No.: 13/510,477

(22) PCT Filed: Nov. 18, 2010
(86) PCT No.: PCT/US10/57205

§ 371 Date: Dec. 4, 2012

Related U.S. Application Data
(60) Provisional application No. 61/262,147, filed on Nov. 18, 2009.

(51) Int. Cl. H05K 1/11

(52) U.S. Cl. CPC H05K 1/115
USPC 361/752

(57) ABSTRACT

A circuit board includes a first and second ground layer and a plurality of signal vias extending between the ground layers but not electrical contact therewith. Ground vias coupled to the first and second ground layers can be positioned adjacent signal vias and can include ground traces that extend between adjacent ground vias. Air holes can be positioned between signal vias and/or adjacent signal vias to modify the electrical performance of the circuit board. Ground wings can be used to help tune common-mode and/or differential-mode impedances.

### CROSS-REFERENCE TO RELATED APPLICATIONS

This application claims priority to U.S. Provisional Application No. 61/262,147, filed Nov. 18, 2009, which is incorporated herein by reference in its entirety.

### BACKGROUND

1. Field of the Invention

The present invention relates to the field of high data-rate capable connectors, more specifically to the field of printed circuit boards suitable for use with high data-rate capable connectors.

2. Description of Related Art

Connectors suitable for transmitting data at high data rates are often mounted on a printed circuit board. One common method of mounting the connector on a circuit board is via the use of terminals that are secured in vias in the circuit board, often by a press-fit or by soldered through hole (or possibly by soldered press-fit). As data rates have increased, the communication systems have increasingly begun to use differential signal coupling as it tends to be more resistant to spurious signals.

One issue that results from the use of differentially coupled signal lines is the need for relatively dense connectors (connectors with a large number of terminals per square inch). These dense connectors require careful engineering in order to provide high data rates such as 12 Gbps or higher. This tends to result in designs that position signal terminals and ground terminals in particular configurations within the connector. While it is possible to control the configuration of the terminals within the connector, it becomes more difficult to maintain this control as the terminals are mated to the circuit board. This is part because the circuit board tends to have a different dielectric constant and in part because the terminal spacing that existed in the connector may be physically impossible to maintain at the connector/circuit board interface due to the limit on how close plated through holes can be positioned together. Thus, as data rates increase, the interface between the connector and a corresponding circuit board becomes more difficult to control in a desired manner. Therefore certain individuals would appreciate an improved circuit board design.

### BRIEF SUMMARY

A circuit board with a first and second ground plane is provided. A void in the first and second ground plane is provided and a first and second signal plated via are positioned in the void. The first and second via may be configured to operate as a differential signal pair. The signal vias may extend through the circuit board so as to provide a shared via design. A plurality of ground vias are positioned adjacent the first and second via and the ground vias couple the first and second ground plane together. Two or more of the ground vias may be coupled together with ground traces. One or more ground via may have a ground wing. If desired, a first unplated air hole is provided in the circuit board adjacent the first and second via and in an embodiment may be positioned substantially between the first and second via. Additional air holes may be provided between signal vias and one or more ground vias. The first air hole is configured to tune coupling between the first and second via. Additional air holes, if used, may be configured to tune coupling between one or both signal vias and one or more ground vias.

### BRIEF DESCRIPTION OF THE DRAWINGS

The present invention is illustrated by way of example and not limited in the accompanying figures in which like reference numerals indicate similar elements and in which:

FIG. 1 illustrates a perspective view of an embodiment of a circuit board.

FIG. 2 illustrates a perspective view of the circuit board depicted in FIG. 1 with the insulative portion removed.

FIG. 3 illustrates a perspective view of a cross-section of the embodiment depicted in FIG. 2 taken along line 3-3.

FIG. 4 illustrates a plan view of an embodiment of a via pattern.

FIG. 5 illustrates a plan view of another embodiment of a via pattern.

### DETAILED DESCRIPTION OF THE INVENTION

The detailed description that follows describes exemplary embodiments and is not intended to be limited to the expressly disclosed combination(s). Therefore, unless otherwise noted, features disclosed herein may be combined together to form additional combinations that were not otherwise shown for purposes of brevity.

Before discussing the various features that are depicted in the attached Figures, it should be noted that not all features may be desirable in all circuit board construction configurations. For example, one goal of circuit board design is to help match the electrical performance in the circuit board with the electrical performance in the connector. As can be appreciated, improving the match in electrical performance (e.g., common-mode impedance) between the circuit board and a corresponding connector helps minimize insertion loss. Furthermore, certain features depicted in the Figures allow for improvements in shielding between differentially coupled vias (thus allowing for substantial decreases in crosstalk between differential via pairs in the circuit board). In addition, the use of ground wings (discussed below) can be helpful to adjust the different coupling between a differential via pair (thus allowing the tuning of differential-mode impedance and common-mode impedance). Selecting the particular features that are helpful will be based, in large part, on the desired performance of the system.

It should be noted that the features discussed herein are most suitable to applications where signaling frequencies are high and the density of the pin field is also high. Noteably, signaling frequencies about 6 GHz and densities of greater than 40 signal pairs per linear inch (when looking at the vias alone) are where the depicted structures and designs have been determined to be more beneficial. In addition, the improvements provided by the depicted structure would not tend to be of as much benefit at lower signal frequencies.

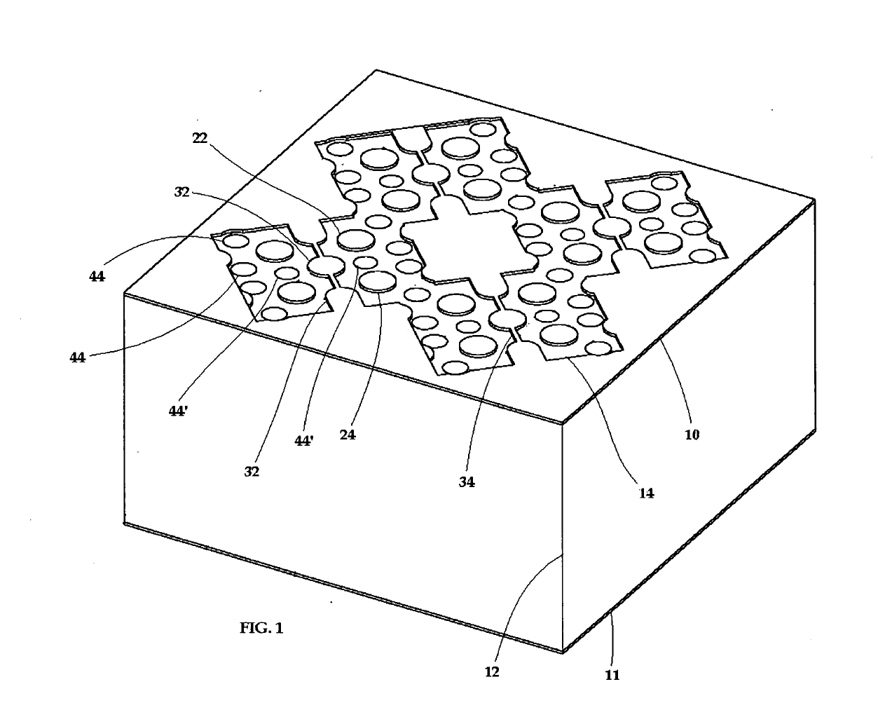

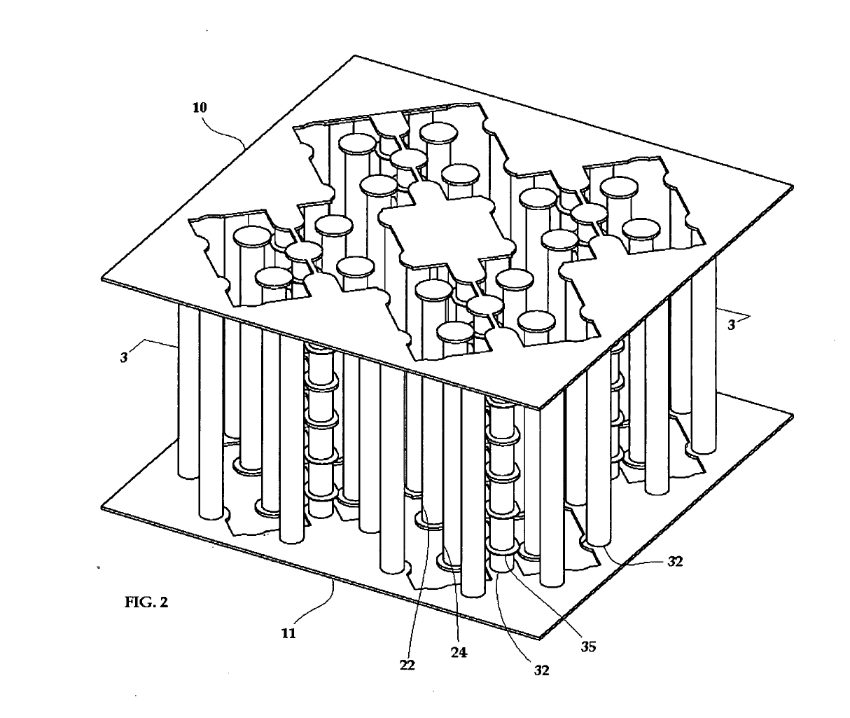

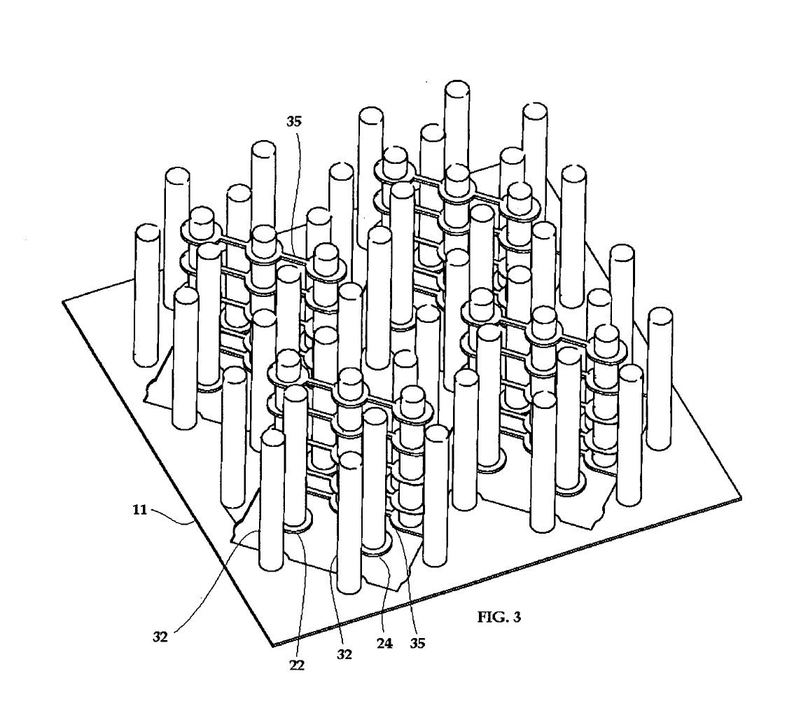

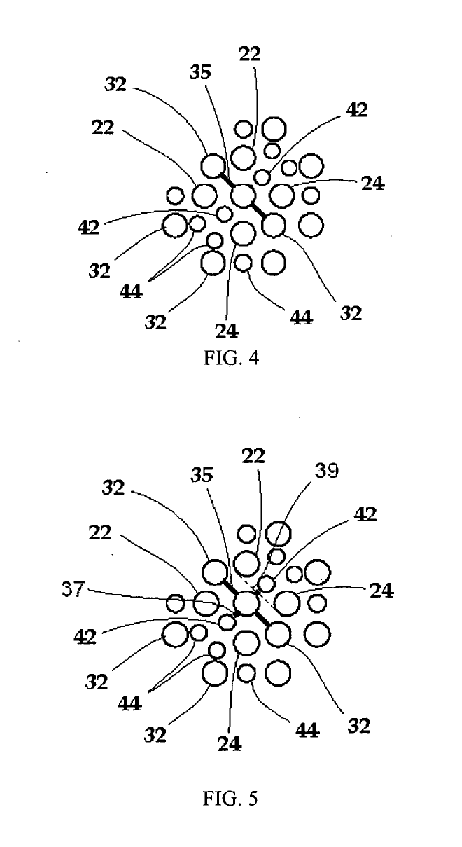

FIGS. 1-5 illustrate features that can be used in various embodiments of a circuit board that includes a first ground layer 10, a second ground layer 11 and an insulative portion 12. As can be appreciated, the two ground planes and the insulative portion provide a circuit board with a first and second side. In operation, the insulative portion can be provided as a number of layers that effectively provide the insulation portion that extends between the two ground planes. Furthermore, while two ground planes are illustrated, additional ground planes could also be provided (each ground plane separated from another ground plane by a corresponding insulation portion), providing a more complex circuit board. In general, each additional ground plane could be configured in a manner similar to how the ground planes 10, 11 are depicted in the figures provided herewith.

Electrically joining the two ground planes 10, 11 are a plurality of ground vias 32. As can be appreciated, the ground vias 32 can be positioned around signal vias 22, 24 in a desired pattern and extends between the two ground planes 10, 11. Some ground vias 32 may extend between the two ground planes 10, 11 in electrical isolation from other ground vias. Two or more ground vias 32 can also be coupled together via one or more ground trace 35 that may be positioned at predetermined locations within the insulative layer 12. The ground traces 35, if positioned often enough, can provide a fence-like shielding that can help reduce cross-talk between signal terminals positioned on opposite sides of the fence formed by the ground traces 35. Or to put it another way, the ground traces provided between two ground vias can be configured so as to provide effective shielding between a first side of the two ground vias and a second side of the two ground vias. As can be appreciated, the periodic use of ground traces between ground vias allows for greater shielding than would be possible with two ground vias alone. For example, as depicted in FIGS. 1-3, three ground vias are positioned in an area between the first differential signal pair and a second differential signal pair and a plurality of ground traces extend between the three ground vias. As can be appreciated, using just two ground vias with ground traces extending between may be suitable in certain applications.

To allow the signal vias 22, 24 to transmit signals between the two sides of the circuit board, there is a void 14 in the ground plane 10, 11 around the signal vias 22, 24. In the past, the area between the signal vias 22, 24 was filled with the insulative portion. As can be appreciated from FIG. 5, in an embodiment the ground plane can include a ground wing 37 so that the ground plane can extend past line 39 (which defines an edge of the area extending between the first via 22 and the second via 24), thus preventing the area extending between the vias from being free of the ground plane. It has been determined that this can be beneficial to help ensure the proper balance between common-mode impedance and differential-mode impedance and can also help provide further shielding. It should be noted that like the ground traces 35 that extend between ground vias, a plurality of ground wings can positioned between the first and second ground plane.

As depicted, a first air hole 44′ is positioned between the first and second signal via 22, 24 and this operates to modify the differential coupling between the first and second signal via 22, 24. The size of the air hole 44′ can be configured as necessary to provide the desired coupling between the first and second signal via. As can be appreciated, the air hole, as it is not plated, can be made smaller than the typical plated via as ratio limitations associated with plated vias don't apply. In an embodiment, the air hole can be between about 0.4-0.6 mm in diameter but naturally the size of the air hole can be varied to provide the desired coupling between the first and second signal via and/or between the signal vias and one or more ground vias.

As depicted, additional air holes 44, which may be the same size as air hole 44′ or may be some other size, can be positioned between ground vias 32 and the signal vias 22, 24. The air holes 44 can help control the coupling between one or both of the signal vias 22, 24 and ground vias 32 so that the overall communication path between the two sides is appropriate and matches the connector design. The location and number of air holes beneficial to provide the desired results will naturally vary depending on system needs and thus, in certain embodiments one or two air holes may be sufficient. Including the air hole 44′ between the first and second signal via 22, 24 has been determined to be advantageous for certain circuit board configurations, particularly as data rates increase above 12 Gbps.

The disclosure provided herein describes features in terms of preferred and exemplary embodiments thereof. Numerous other embodiments, modifications and variations within the scope and spirit of the appended claims will occur to persons of ordinary skill in the art from a review of this disclosure.

We claim:

1. A circuit board, comprising:
a first ground plane;
a second ground plane;
an insulative portion provided between the first and second ground plane;
a first and second signal via extending between the first and second ground plane, the first and second signal via configured to provide a differential signal pair, the first and second signal via being electrically isolated from the first and second ground plane and having an area that extends between the first and second signal via; and
an air hole positioned in the area that extends between the first and second signal via.

2. The circuit board of claim 1, wherein the air hole has a first diameter and the signal vias have a second diameter that is greater than the first diameter.

3. The circuit board of claim 2, wherein the air hole is a first air hole and a second air hole is positioned adjacent one of the first and second signal vias but is not positioned in the area that extends between the first and second signal via.

4. The circuit board of claim 3, further comprising a first ground via extending between the first and second ground plane, the first ground via electrically coupled to the first and second ground plane, wherein the second air hole is at least partially positioned in a second area that extends between the first ground via and one of the first and second signal via.

5. A circuit board, comprising:
a first ground plane;
a second ground plane;
an insulative portion provided between the first and second ground plane;
a first and second differential via pair extending between the first and second ground plane, each of the first and second differential via pair being configured to provide a differential signal transmission channel, the first and second signal via being electrically isolated from the first and second ground plane and having an area that extends between the first and second differential via pair; and
two ground vias positioned in the area, the ground vias electrically coupled to the first and second ground plane and further including a plurality of ground traces extending between the two ground vias, the plurality of ground traces positioned between the first and second ground.

6. The circuit board of claim 5, wherein a third ground via is positioned adjacent one of the two ground vias and a plurality of ground traces extend between the third ground via and the corresponding one of the two ground vias.

7. The circuit board of claim 6, wherein the three ground vias are in a straight line.

8. The circuit board of claim 7, wherein the three ground vias include two end ground vias and one middle ground via, wherein a ground wing extends from the middle ground via such that it extends into an area between the signal vias that form the first differential via pair.

9. The circuit board of claim 8, wherein the ground wing is a first ground wing that extends in a first direction and a second ground wing extends from the middle ground via in a second direction.
